(19) United States
(12) Patent Application Publication
(10) Pub. No.: US 2022/0190152 A1
(43) Pub. Date: Jun. 16, 2022

(54) SEMICONDUCTOR DEVICE

(71) Applicant: Panasonic Intellectual Property Management Co., Ltd., Osaka (JP)

(72) Inventors: Hideyuki OKITA, Toyama (JP); Masahiro HIKITA, Toyama (JP); Yasuhiro UEMOTO, Osaka (JP)

(21) Appl. No.: 17/688,440

(22) Filed: Mar. 7, 2022

Related U.S. Application Data
(62) Division of application No. 15/958,075, filed on Apr. 20, 2018.
Application No. 15/958,075 is a continuation of application No. PCT/JP2016/004679, filed on Oct. 25, 2016.

(30) Foreign Application Priority Data
Oct. 27, 2015 (JP) 2015-211254

(51) Int. Cl. H01L 29/778; H01L 29/10; H01L 27/098; H01L 29/808; H01L 29/66

(52) U.S. Cl. CPC H01L 29/7787; H01L 29/1058; H01L 29/7786; H01L 27/098; H01L 29/2003; H01L 29/1029; H01L 29/1066; H01L 29/66462; H01L 29/808

(57) ABSTRACT

A semiconductor device includes: a substrate; a channel layer constituted of a single nitride semiconductor on the substrate; a first barrier layer which is a nitride semiconductor on a part of an upper surface of the channel layer and having a band gap larger than that of the channel layer; a gate layer which is a nitride semiconductor on and in contact with the first barrier layer; a second barrier layer which is a nitride semiconductor in contact with the first barrier layer in an area where the gate layer is not disposed above the channel layer, and having a band gap larger than that of the channel layer and having a thickness or a band gap independent from the first barrier layer; a gate electrode on the gate layer; and a source electrode and a drain electrode spaced apart from the gate layer and on the second barrier layer.

### CROSS REFERENCE TO RELATED APPLICATIONS

This application is a Divisional of U.S. patent application Ser. No. 15/958,075 filed on Apr. 20, 2018, which is a U.S. continuation application of PCT International Patent Application Number PCT/JP2016/004679 filed on Oct. 25, 2016, claiming the benefit of priority of Japanese Patent Application Number 2015-211254 filed on Oct. 27, 2015, the entire contents of which are hereby incorporated by reference.

### BACKGROUND

### 1. Technical Field

The present disclosure relates to a semiconductor device, and particularly to a technique to improve characteristics of gate leakage current and current collapse of a semiconductor device.

### 2. Description of the Related Art

Semiconductor devices constituted of group-III nitride semiconductor (hereinafter, referred to as group-III nitride semiconductor devices) are well known (see, for example, Japanese Patent No. 5492919, and Japanese Unexamined Patent Application Publication Nos. 2010-225765 and 2008-210836). In particular, a group-III nitride semiconductor device which uses GaN (Gallium Nitride) and AlGaN (Aluminum Gallium Nitride) has a high insulation break-down voltage because such materials have a wide band gap.

Further, in a group-III nitride semiconductor device, a hetero structure such as an AlGaN/GaN can be formed easily. In the hetero structure, a channel (hereinafter, referred to as a 2DEG channel) due to high concentration electrons (two-dimensional electron gas, 2DEG) is generated on the side of the GaN layer at the AlGaN/GaN interface due to a piezo-electric charge generated through a lattice constant difference between materials and difference in band gap between materials. The 2DEG channel enables a large-current operation and high-speed operation of a semiconductor device.

A field effect transistor (FET) which operates by controlling a 2DEG channel is generally referred to as a high electron mobility transistor (HEMT).

Because of these features, group-III nitride semiconductor devices are applied to FETs and diodes etc. for power applications.

### SUMMARY

However, in the group-III nitride semiconductor devices disclosed in Japanese Patent No. 5492919, and Japanese Unexamined Patent Application Publication Nos. 2010-225765 and 2008-210836, there is a room for improvement in gate leakage current and current collapse. Accordingly, the present disclosure provides a semiconductor device of which gate leakage current and current collapse characteristics are improved.

A semiconductor device according to an aspect of the present disclosure includes: a substrate; a channel layer which is constituted of a single nitride semiconductor disposed on the substrate; a first barrier layer which is a nitride semiconductor disposed on and in contact with a selected part of an upper surface of the channel layer and having a band gap larger than a band gap of the channel layer; a gate layer which is a nitride semiconductor disposed on and in contact with the first barrier layer; a second barrier layer which is a nitride semiconductor disposed in contact with the first barrier layer in an area where the gate layer is not disposed above the channel layer, and having a band gap larger than the band gap of the channel layer and having a thickness or a band gap independently set with respect to the first barrier layer; a gate electrode which is disposed on the gate layer; and a source electrode and a drain electrode which are spaced apart from the gate layer and disposed on the second barrier layer.

In the above described semiconductor device, since a threshold voltage Vth is dependent substantially only on a thickness of the first barrier layer, it is possible to decrease variation in the threshold voltage Vth in a wafer by, for example, forming the first barrier layer through epitaxy with an excellent thickness controllability. Further, for example, when the gate layer is constituted of a semiconductor material of p-type, it is possible, by using a depletion layer of a p-n junction, to easily realize a normally-off-operation in which the threshold voltage Vth is positive and, at the same time, reduce the gate leakage current.

Further, it is also possible to suppress occurrence of current collapse by providing a thick second barrier layer in the vicinity of the gate end on the drain side where strong electric field concentration occurs, thereby physically separating the semiconductor surface (that is, the surface of the second barrier layer) from the 2DEG.

Moreover, electrons captured in a surface level and impurity level at the surface of the second barrier layer, etc. can be cancelled by holes injected from a p-type layer when a positive voltage is applied to the gate electrode, thus suppressing the occurrence of current collapse. Further, since the On-resistance is substantially determined by the thickness of the second barrier layer, it is possible to decrease the variation of On-resistance in a wafer. Further, by fully removing the first barrier layer, into which a p-type impurity has diffused, in an area other than directly beneath the gate, it is possible to inhibit the occurrence of gate leakage current at a high voltage, which flows in the p-type impurity diffusion layer.

### BRIEF DESCRIPTION OF DRAWINGS

These and other objects, advantages and features of the disclosure will become apparent from the following description thereof taken in conjunction with the accompanying drawings that illustrate a specific embodiment of the present disclosure.

FIG. 1 is a cross-sectional view to show the structure of a semiconductor device based on the description of Japanese Patent No. 5492919;

FIG. 2 is a cross-sectional view to show the structure of a semiconductor device based on the description of Japanese Unexamined Patent Application Publication No. 2010-225765;

FIG. 3 is a cross-sectional view to show a structure in which a p-type gate layer is added to the structure of a semiconductor device based on the description of Japanese Unexamined Patent Application Publication No. 2008-210836;

FIG. 4 is a cross-sectional view to show an example of the structure of a semiconductor device according to Embodiment 1;

FIG. 5 is a cross-sectional view to show an example of the structure of a semiconductor device according to a variation of Embodiment 1;

FIG. 6 is a cross-sectional view to show an example of the structure of a semiconductor device according to a variation of Embodiment 1;

FIG. 7 is a cross-sectional view to show an example of the structure of a semiconductor device according to a variation of Embodiment 1;

FIG. 8 is a cross-sectional view to show an example of the structure of a semiconductor device according to a variation of Embodiment 1;

FIG. 9 is a cross-sectional view to show an example of the structure of a semiconductor device according to a variation of Embodiment 1;

FIG. 10 is a cross-sectional view to show an example of the structure of a semiconductor device according to a variation of Embodiment 1;

FIG. 11 is a cross-sectional view to show an example of the structure of a semiconductor device according to a variation of Embodiment 1;

FIG. 12 is a cross-sectional view to show an example of the structure of a semiconductor device according to a variation of Embodiment 1;

FIG. 13 is a cross-sectional view to show an example of the structure of a semiconductor device according to a variation of Embodiment 1;

FIG. 14 is a cross-sectional view to show an example of the structure of a semiconductor device according to a variation of Embodiment 1;

FIG. 15A is a diagram to show an example of the manufacturing process of the semiconductor device according to Embodiment 1;

FIG. 15B is a diagram to show an example of the manufacturing process of the semiconductor device according to Embodiment 1;

FIG. 15C is a diagram to show an example of the manufacturing process of the semiconductor device according to Embodiment 1;

FIG. 15D is a diagram to show an example of the manufacturing process of the semiconductor device according to Embodiment 1;

FIG. 15E is a diagram to show an example of the manufacturing process of the semiconductor device according to Embodiment 1;

FIG. 15F is a diagram to show an example of the manufacturing process of the semiconductor device according to Embodiment 1;

FIG. 16 is a cross-sectional view to show an example of the structure of a semiconductor device according to Embodiment 2;

FIG. 17 is a cross-sectional view to show an example of the structure of a semiconductor device according to a variation of Embodiment 2;

FIG. 18A is a diagram to show an example of the manufacturing process of a semiconductor device according to Embodiment 2;

FIG. 18B is a diagram to show an example of the manufacturing process of the semiconductor device according to Embodiment 2;

FIG. 18C is a diagram to show an example of the manufacturing process of the semiconductor device according to Embodiment 2;

FIG. 18D is a diagram to show an example of the manufacturing process of the semiconductor device according to Embodiment 2;

FIG. 18E is a diagram to show an example of the manufacturing process of the semiconductor device according to Embodiment 2;

FIG. 18F is a diagram to show an example of the manufacturing process of the semiconductor device according to Embodiment 2;

FIG. 19A is a plan view to show an example of the layout of electrodes of a semiconductor device according Embodiment 3;

FIG. 19B is a plan view to show an example of the layout of electrodes of the semiconductor device according Embodiment 3;

FIG. 19C is a plan view to show an example of the layout of electrodes of the semiconductor device according Embodiment 3;

FIG. 19D is a plan view to show an example of the layout of electrodes of the semiconductor device according Embodiment 3; and

FIG. 19E is a plan view to show an example of the layout of electrodes of the semiconductor device according Embodiment 3.

### DETAILED DESCRIPTION OF THE EMBODIMENTS

### Findings Forming Basis of Present Disclosure

The present inventors have found that there is a room for further improvement in characteristics of gate leakage current and current collapse of semiconductor devices described in Japanese Patent No. 5492919, and Japanese Unexamined Patent Application Publication Nos. 2010-225765 and 2008-210836 mentioned in Description of the Related Art.

Note that although the gate leakage current generally refers to a current that flows between gate and drain, and between gate and source, the present description addresses a gate leakage current that flows between gate and drain of an FET in an Off-state.

Further, current collapse (also referred to as current slump) refers to a phenomenon in which drain current flowing in an FET in an On-state is hindered. This phenomenon occurs as a result of electrons being captured in a surface level, an impurity level, levels caused by crystal defects of a semiconductor, and the like. More specifically, electrons captured in the above described levels during an Off-state and an On-state of an FET remain in the concerned levels during an On-state to form a depletion layer in the surrounding, thereby hindering drain current. In a HEMT constituted of GaN, generally, the surface level of semiconductor is considered to be closely related to current collapse.

First, for the purpose of comparison with a semiconductor device of the present disclosure, the structure of a HEMT assumed by the present inventor will be described based on descriptions of Japanese Patent No. 5492919, and Japanese Unexamined Patent Application Publication Nos. 2010-225765 and 2008-210836.

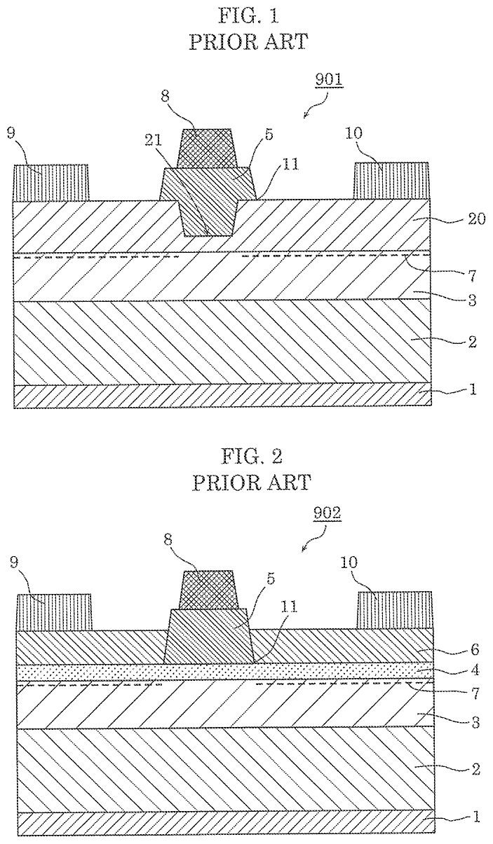

FIG. 1 is a cross-sectional view to show an example structure of HEMT 901 based on the description of Japanese Patent No. 5492919.

HEMT 901 shown in FIG. 1 is configured as follows. Buffer layer 2 is formed on substrate 1, and channel layer 3 (GaN, etc.) is formed further above buffer layer 2. Further, barrier layer 20 (AlGaN, etc.) having a band gap larger than that of channel layer 3 is formed above channel layer 3. As a result of this, 2DEG 7 occurs due to a band gap difference between barrier layer 20 and channel layer 3, and a piezo-electric charge in barrier layer 20.

Further, recess 21 is formed in a part of barrier layer 20, and gate layer 5 (p-GaN, etc.) of a p-type semiconductor is formed so as to embed recess 21. Gate electrode 8 is formed above gate layer 5, and source electrode 9 and drain electrode 10, which are in ohmic contact with barrier layer 20, are formed so as to be spaced apart on both sides of gate electrode 8.

In HEMT 901, by providing p-type gate layer 5, it is possible to form a p-n junction between gate electrode 8 and 2DEG 7, thereby realizing a normally-off operation, and at the same time to reduce the gate leakage current. Moreover, by embedding gate layer 5 in recess 21, it is possible to realize a normally-off operation, and at the same time to keep 2DEG 7 and the surface (upper surface in FIG. 1) of barrier layer 20 to be physically apart from each other, thus reducing current collapse.

FIG. 2 is a cross-sectional view to show an example structure of a HEMT based on the description of Japanese Unexamined Patent Application Publication No. 2010-225765.

HEMT 902 shown in FIG. 2 is configured as follows. Buffer layer 2 is formed on substrate 1, and further channel layer 3 (GaN, etc.) is formed above buffer layer 2. Further above channel layer 3, first barrier layer 4 (AlGaN, etc.), which has a larger band gap than that of channel layer 3, and gate layer 5 (p-GaN, etc.) of a p-type conductor are formed consecutively.

After selectively removing gate layer 5, second barrier layer 6 (AlGaN, etc.) is selectively formed in an area where gate layer 5 is removed. Gate electrode 8 is formed above gate layer 5, and source electrode 9 and drain electrode 10, which are in ohmic contact with second barrier layer 6, are formed so as to be spaced apart on both sides of gate electrode 8.

In HEMT 902, since threshold voltage Vth is substantially determined by a thickness of first barrier layer 4, it is possible to decrease the variation of threshold voltage Vth in a wafer by forming first barrier layer 4 through an epitaxy with an excellent thickness controllability.

Further, as with HEMT 901, by forming barrier layer 20 and p-type gate layer 5 consecutively, it is possible to form a p-n junction between gate electrode 8 and 2DEG 7, thereby realizing a normally-off operation, and at the same time to reduce gate leakage current. Further, by forming second barrier layer 6, it is possible to keep 2DEG 7 and the surface (upper surface in FIG. 2) of second barrier layer 6 to be physically apart from each other, thereby reducing current collapse.

FIG. 3 is a cross-sectional view to show an example structure of a HEMT in which gate layer 5 of a p-type semiconductor (p-GaN, etc.) is added to the structure of a HEMT based on the description of Japanese Unexamined Patent Application Publication No. 2008-210836.

HEMT 903 shown in FIG. 3 is configured as follows. Buffer layer 2 is formed on substrate 1, and further channel layer 3 (GaN, etc.) having protrusion 22 is formed above buffer layer 2. Next, barrier layer 20 (AlGaN, etc.), which has a larger band gap than that of channel layer 3, is formed so as to cover protrusion 22, and further p-type gate layer 5 is selectively formed above barrier layer 20. Gate electrode 8 is formed above p-type gate layer 5, and source electrode 9 and drain electrode 10, which are in ohmic contact with barrier layer 20, are formed so as to be spaced apart on both sides of gate electrode 8.

According to HEMT 903, a portion covering side surface 23 of protrusion 22, out of barrier layer 20 covering protrusion 22 of channel layer 3, becomes thin due to low lateral growth rate of epitaxy. Therefore, it is possible to realize a normally-off operation by using the concerned thin portion of barrier layer 20.

Moreover, as with HEMT 902, it is possible to decrease the variation of threshold voltage Vth in a wafer by forming barrier layer 20 through epitaxy.

Further, as in HEMT 902, by forming barrier layer 20 and p-type gate layer 5 consecutively, it is possible to form a p-n junction between gate electrode 8 and 2DEG 7, thereby realizing a normally-off operation, and at the same time to reduce gate leakage current. Further, it is possible to keep 2DEG 7 and the surface (upper face in FIG. 3) of second barrier layer 6 to be physically apart from each other in an area other than the gate area, thereby reducing current collapse.

In this way, in HEMTs 901 to 903 which are configured based on the concepts of Japanese Patent No. 5492919, and Japanese Unexamined Patent Application Publication Nos. 2010-225765 and 2008-210836, it is possible to reduce gate leakage current and current collapse.

However, the present inventors have noticed that there are the following concerns with HEMTs 901 to 903, which may impair reducing effect of gate leakage current and current collapse.

The first concern is that in HEMT 901, variation of threshold voltage Vth is likely to increase in a wafer. The threshold voltage Vth of HEMT 901 is determined substantially by a thickness of barrier layer 20 which is remained directly beneath recess 21 (hereinafter, referred to as a remained thickness). However, since there is no etching stopper layer, etc. in HEMT 901, two factors that determine the remained thickness of barrier layer 20 are an initial thickness of barrier layer 20 and a depth of recess 21. Therefore, it is difficult to increase uniformity of the remained thickness of barrier layer 20, and the variation of threshold voltage Vth is likely to increase between wafers in HEMT 901.

The second concern is that the variation of On-resistance is likely to increase in a wafer in HEMTs 901 to 903. In HEMTs 901 to 903, generally, the surface of barrier layer 20 or first barrier layer 4 is removed to a depth of several nm to several tens of nm by performing over etching when selectively etching and removing gate layer 5. For that reason, the variation of the thickness of barrier layer 20 or first barrier layer 4 increases in a wafer, the uniformity of distribution of 2DEG 7 is impaired, and consequently the variation of On-resistance of HEMTs 901 to 903 in a wafer increases.

The third concern is that leaking defect of gate current is likely to occur when high voltage is applied in HEMTs 901 to 903. In HEMTs 901 to 903, p-type impurities (Mg, etc.) may be diffused into barrier layer 20 or first barrier layer 4 with a high concentration when p-type gate layer 5 is formed through epitaxial regrowth. For that reason, when a high voltage (for example, a voltage of several hundreds of volt which is commonly used in a power semiconductor) is applied in HEMTs 901 to 903, there is concern that gate current may leak through an area into which the concerned p-type impurity has diffused.

The present inventors have conducted diligent work on a semiconductor device which can resolve the above described concerns and is excellent in reducing gate leakage current and current collapse to eventually reach a semiconductor device according to the present disclosure.

### Embodiment 1

A semiconductor device according to Embodiment 1 is a semiconductor device which has a first barrier layer directly beneath a gate layer, and a second barrier layer, which is thicker than the first barrier layer, in an area other than the area directly beneath the gate layer. Embodiment 1 shows a non-limiting example of a minimum configuration of the semiconductor device according to Embodiment 1.

### Structure of Semiconductor Device

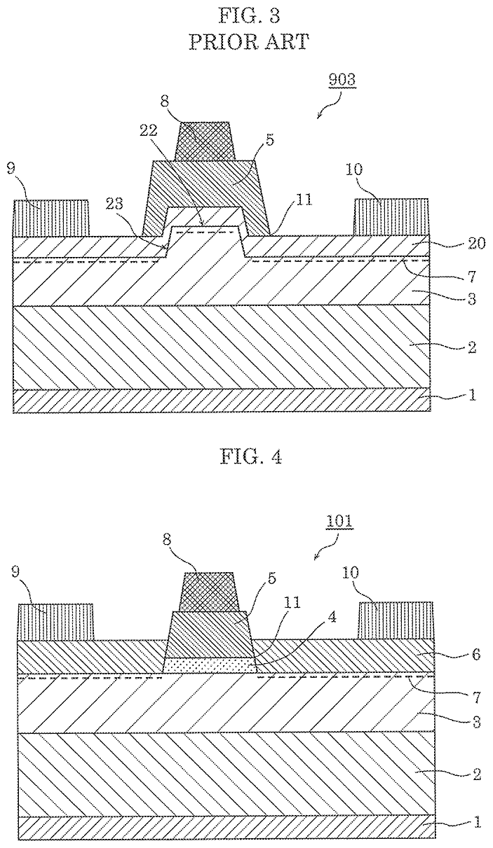

FIG. 4 is a cross-sectional view to show an example of the structure of the semiconductor device according to Embodiment 1. Hereinafter, although description will be made on an example in which semiconductor device 101 is constituted of a group-III nitride semiconductor, semiconductor device 101 may be constituted of another compound, for example, a group III-V semiconductor or a group II-VI semiconductor.

As shown in FIG. 4, semiconductor device 101 includes: substrate 1; buffer layer 2 disposed on substrate 1 and channel layer 3 which is constituted of a single nitride semiconductor; first barrier layer 4 which is disposed on and in contact with a selected part of an upper surface of channel layer 3 and which is a nitride semiconductor having a band gap larger than a band gap of channel layer 3; gate layer 5 which is a nitride semiconductor disposed on and in contact with first barrier layer 4; second barrier layer 6 which is a nitride semiconductor disposed in contact with first barrier layer 4 in an area where gate layer 5 is not disposed above channel layer 3, and having a band gap larger than the band gap of channel layer 3 and having a thickness or a band gap independently set with respect to first barrier layer 4; a gate electrode which is disposed on gate layer 5; and source electrode 9 and drain electrode 10 which are spaced apart from gate layer 5 and are disposed on second barrier layer 6.

Substrate 1 may be constituted of, for example, an Si substrate of a (111) crystal plane, as well as a substrate of sapphire, SiC, GaN, AlN, or the like.

Buffer layer 2 may be constituted of, for example, a single layer or plural layers of GaN, AlGaN, AlN, InGaN, AlInGaN, or the like.

Channel layer 3 may be constituted of, for example, GaN, as well as InGaN, AlGaN, AlInGaN, or the like.

First barrier layer 4 may be constituted of, for example, AlGaN as well as GaN, InGaN, AlGaN, AlInGaN, or the like.

Gate layer 5 may be constituted of, for example, a p-type semiconductor including p-GaN, as well as p-InGaN, p-AlGaN, p-AlInGaN, or the like.

In the example of FIG. 4, second barrier layer 6 is thicker than first barrier layer 4, and is constituted of a material having a band gap larger than that of channel layer 3. For example, second barrier layer 6 may be constituted of AlGaN, and channel layer 3 may be constituted of GaN. In this case, due to piezo-electric charge caused by lattice constant difference between AlGaN and GaN, and band gap difference between them, a high concentration 2DEG 7 is generated on the GaN layer side in the vicinity of AlGaN/GaN interface (that is, in channel layer 3 directly beneath second barrier layer 6).

Gate electrode 8 is a metal electrode which is in ohmic contact or in Schottky contact with gate layer 5. Gate electrode 8 is constituted of, for example, a combination of one or more metals such as Ti, Ni, Pd, Pt, Au, W, WSi, Ta, TiN, Al, Mo, Hf, and Zr.

Source electrode 9 and drain electrode 10 are a metal electrode which is ohmic contact with at least one of 2DEG 7, second barrier layer 6, and channel layer 3. Source electrode 9 and drain electrode 10 are constituted of, for example, a combination of one or more metals such as Ti, Al, Mo, and Hf. Source electrode 9 and drain electrode 10 may be formed on, for example, the surface of second barrier layer 6, and may also be formed so as to be in contact with at least one of second barrier layer 6, 2DEG 7, and channel layer 3 by using a known ohmic recess structure (not shown).

First barrier layer 4 is constituted of a material having a larger band gap than that of channel layer 3. For that reason, 2DEG may occur in channel layer 3 directly beneath first barrier layer 4 in the same mechanism as that in which 2DEG 7 occurs in channel layer 3 directly beneath second barrier layer 6.

On the other hand, unlike second barrier layer 6, first barrier layer 4 is p-n joined with gate layer 5 which is constituted of a p-type semiconductor. As a result of that, when no gate voltage is applied to gate electrode 8, 2DEG directly beneath first barrier layer 4 disappears due to the depletion layer of the concerned p-n junction, and thus no current flows between the source and drain.

In this way, by constituting gate layer 5 with a p-type semiconductor, a normally-off operation is realized by a depletion layer of p-n junction, and also gate leakage current is reduced. For example, when first barrier layer 4 is constituted of AlGaN containing, in composition ratio, 20% of Al, a normally-off operation is realized by configuring that the thickness of first barrier layer 4 is less than or equal to 20 nm.

Moreover, if a film thickness of second barrier layer 6 is small, and a distance from channel layer 3 to the surface (the upper surface in the figure) of second barrier layer 6 is too small, a large current collapse occurs due to electrons captured in the surface level of second barrier layer 6. For that reason, a film thickness of second barrier layer 6 in the vicinity of gate end 11 is made larger than that of first barrier layer 4 and more than or equal to 20 nm. Especially, for uses for a general purpose power semiconductor element of at least 600 rated voltage, the film thickness of second barrier layer 6 may be more than or equal to 30 nm (for example, about 100 nm which is a critical film thickness of epitaxy).

Semiconductor device 101 configured as described above performs normally-off operation as follows. That is, when no gate voltage is applied to gate electrode 8, since a depletion layer spreads directly beneath gate layer 5, no 2DEG is present and semiconductor device 101 is in an Off-state. When a positive gate voltage more than a threshold voltage Vth is applied to gate electrode 8 with source electrode 9 being grounded and drain electrode 10 applied with a positive load voltage, 2DEG occurs below the gate and is connected with left and right 2DEG causing a drain current to flow, so that semiconductor device 101 turns into an On-state (not shown).

In a general purpose power semiconductor element with a rated voltage of 600 V, a load voltage of at most 600 V is applied to the source and drain when in Off-state. Transition times from Off-state to On-state and from On-state to Off-state in such a general purpose power semiconductor element are both at least several nanoseconds to several tens of nanoseconds.

According to semiconductor device 101 configured as described above, the following effects can be obtained.

The threshold voltage Vth of semiconductor device 101 is substantially dependent on the thickness of first barrier layer 4. By forming first barrier layer 4 by using epitaxy such as MOCVD (Metal Organic Chemical Vapor Deposition) which exhibits an excellent thickness controllability, it is possible to decrease the variation of threshold voltage Vth in a wafer plane.

Moreover, by constituting gate layer 5 with a p-type semiconductor material, it is possible to realize a normally-off operation by using a depletion layer of a p-n junction, and at the same time to reduce gate leakage current.

Further, by providing thick second barrier layer 6 in the vicinity of gate end 11 on the drain side in which strong electric field concentration occurs, to physically separate the surface of the semiconductor layer (here, the surface of second barrier layer 6) from channel layer 3 including 2DEG 7, it is possible to suppress occurrence of current collapse.

Moreover, since electrons captured in a surface level and impurity level at the surface of second barrier layer 6, etc. are cancelled by holes injected from p-type gate layer 5 when a positive voltage is applied to gate electrode 8, it is possible to suppress the occurrence of current collapse.

Moreover, the On-resistance of semiconductor device 101 is dependent on the thickness of second barrier layer 6. For that reason, by forming second barrier layer 6 by using epitaxy such as MOCVD which exhibits an excellent thickness controllability, it is possible to decrease variation of On-resistance in a wafer plane.

Next, various variations of semiconductor device 101 described above will be described. It is noted that a component equivalent to a component of semiconductor device 101 is denoted by the same symbol, and regarding matters equivalent to those of semiconductor device 101, description thereof will be appropriately omitted by applying the above described description.

### Variation 1

In an actual semiconductor device, impurities contained in gate layer 5 may diffuse into first barrier layer 4 when gate layer 5 is formed. Such a case will be described in Variation 1.

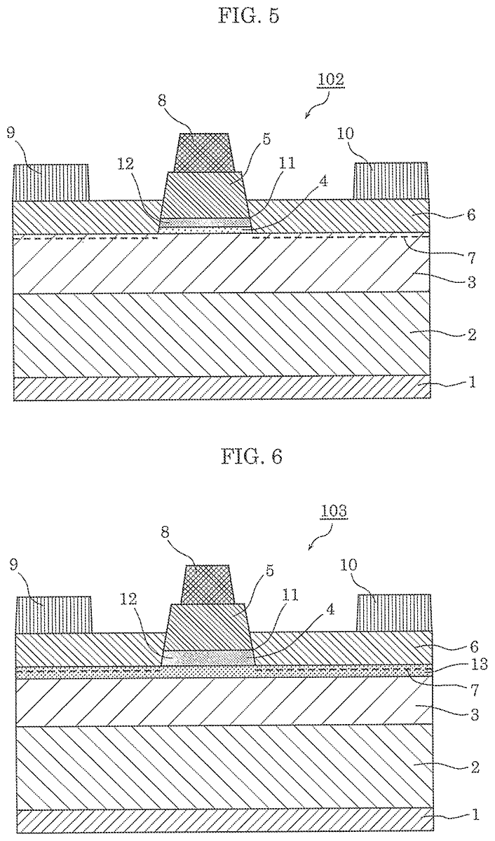

FIG. 5 is a cross-sectional view to show an example of the structure of a semiconductor device according to Variation 1. Semiconductor device 102 shown in FIG. 5 is different, compared to semiconductor device 101 of FIG. 4, in that p-type impurities added to gate layer 5 diffuse to first barrier layer 4, thus forming diffusion layer 12 in first barrier layer 4. Diffusion layer 12 is formed in first barrier layer 4 below gate layer 5 and is not formed in second barrier layer 6.

As a specific example, in semiconductor device 102, the concentration of p-type impurities contained in first barrier layer 4 may be more than or equal to 1E18 cm⁻³, and the concentration of the p-type impurities contained in second barrier layer 6 may be less than 1E18 cm⁻³. Where, 1EX cm⁻³ means 1×10^{X} cm⁻³, and the same notation will be used hereinafter.

Such a structure may be formed by, for example, fully removing an unnecessary portion of gate layer 5, as well as first barrier layer 4, which lies directly beneath the unnecessary portion, together with diffusion layer 12 when patterning of gate layer 5 is performed.

According to thus configured semiconductor device 102, the same effects as those of semiconductor device 101 can be obtained. Moreover, since in semiconductor device 102, diffusion layer 12 which works as a leakage path of gate current is fully removed in an area other than directly beneath gate layer 5, leakage of gate current when a high voltage is applied in semiconductor device 102 is suppressed.

### Variation 2

In an actual semiconductor device, impurities added to gate layer 5 may diffuse into channel layer 3 depending on the impurity concentration of gate layer 5 and process conditions (temperature and time, etc.) for forming gate layer 5. In Variation 2, such a case will be described.

FIG. 6 is a cross-sectional view to show an example of the structure of a semiconductor device according to Variation 2. Semiconductor device 103 shown in FIG. 6 is, compared to semiconductor devices 101 and 102 of FIGS. 4 and 5, different in the following points. P-type impurities added to gate layer 5 diffuse to channel layer 3, thus forming diffusion layer 12 in entire first barrier layer 4, and further, diffusion layer 13 is formed in channel layer 3.

As a specific example, in semiconductor device 103, the concentration of p-type impurities contained in first barrier layer 4 may be more than or equal to 1E18 cm⁻³, and the concentration of the p-type impurities contained in channel layer 3 (particularly, diffusion layer 13) directly beneath second barrier layer 6 may be less than 1E18 cm⁻³. Such a structure may be formed by, for example, optimizing the impurity concentration of gate layer 5, and process conditions for forming gate layer 5.

According to thus configured semiconductor device 103, it is possible to obtain, in addition to the same effects as those of semiconductor devices 101 and 102, an effect of suppressing leakage of gate current when a high voltage is applied in semiconductor device 103 by suppressing the concentration of impurities contained in diffusion layer 13.

### Variation 3

In the above described semiconductor devices 101 to 103, although the lower surface of first barrier layer 4 and the lower surface of second barrier layer 6 are shown at the same height, the lower surface of second barrier layer 6 may be located at a position lower than the lower surface of first barrier layer 4. In Variation 3, such a case will be described.

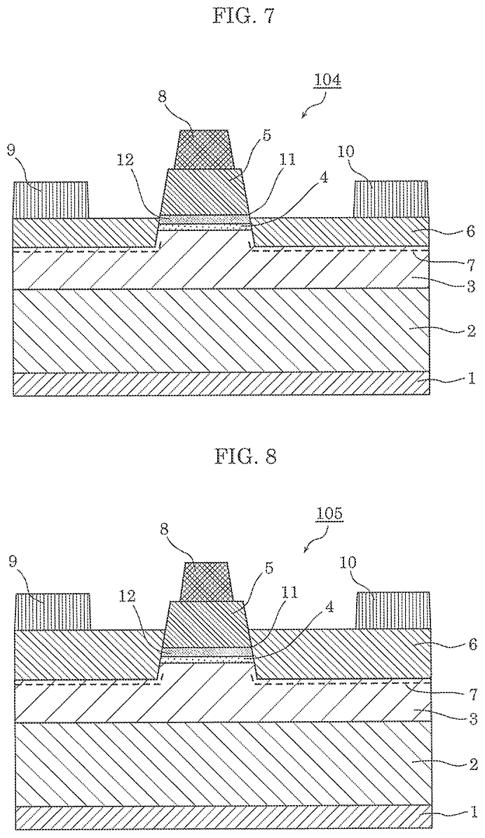

FIG. 7 is a cross-sectional view to show an example of the structure of a semiconductor device according to Variation 3. Semiconductor device 104 shown in FIG. 7 is different, compared to semiconductor devices 101 to 103 of FIGS. 4 to 6, in that the lower surface of second barrier layer 6 is located at a position lower than the lower surface of first barrier layer 4. The thickness of second barrier layer 6 may the same as those of semiconductor devices 101 to 103, and therefore, the upper surface of second barrier layer 6 is located at a position lower than the upper surface (that is, the upper surface of diffusion layer 12 formed within barrier layer 4) of first barrier layer 4 and higher than the lower surface of first barrier layer 4. That is, second barrier layer 6 is in contact with at least a part of the side surface of first barrier layer 4.

Such a structure may be formed by, for example, performing over etching when patterning of gate layer 5 is performed, thereby fully removing unnecessary portion of gate layer 5, as well as first barrier layer 4 together with diffusion layer 12, and further removing the surface layer of channel layer 3.

According to thus configured semiconductor device 104, the same effects as those of semiconductor devices 101 to 103 can be obtained. Further, since diffusion layer 12 in an area other than gate layer 5 is surely removed even when there is variation in the depth of etching in a wafer plane, it is possible to more securely suppress leakage of gate current when a high voltage is applied in semiconductor device 104.

### Variation 4

In the above described semiconductor device 104, although the upper surface of second barrier layer 6 is shown at a position lower than the upper surface of first barrier layer 4 (that is, the upper surface of diffusion layer 12 formed in barrier layer 4) and higher than the lower surface of first barrier layer 4, the upper surface of second barrier layer 6 may be located at a position higher than the upper surface of first barrier layer 4. In Variation 4, such a case will be described.

FIG. 8 is a cross-sectional view to show an example of the structure of a semiconductor device according to Variation 4. Semiconductor device 105 shown in FIG. 8 is different, compared to semiconductor devices 101 to 103, in that the lower surface of second barrier layer 6 is located at a position lower than the lower surface of first barrier layer 4. Moreover, it is also different, compared to semiconductor device 104, in that the upper surface of second barrier layer 6 is located at a position higher than the upper surface of first barrier layer 4.

Such a structure may be formed, as a specific example, by providing second barrier layer 6 so as to be thicker than first barrier layer 4 in semiconductor device 104.

According to thus configured semiconductor device 105, the same effects as those of semiconductor devices 101 to 104 can be obtained. Further, by providing a thick second barrier layer 6 to keep the surface of second barrier layer 6 and 2DEG 7 to be physically apart from each other in the vicinity of gate end 11 on the drain side where electric field is most concentrated, it is possible to reduce current collapse.

### Variation 5

In the above described semiconductor devices 101 to 105, it is assumed that the band gap of first barrier layer 4 and the band gap of second barrier layer 6 are set independently, and the relationship between these band gaps is not particularly specified. However, as one example, the band gap of second barrier layer 6 may be larger than the band gap of first barrier layer 4. Such a case will be described in Variation 5.

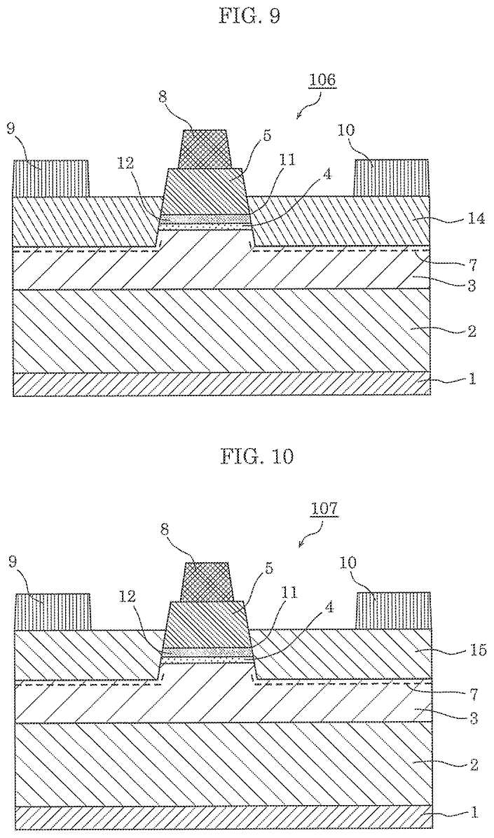

FIG. 9 is a cross-sectional view to show an example of the structure of a semiconductor device according to Variation 5. Semiconductor device 106 shown in FIG. 9 is configured by substituting second barrier layer 6 of semiconductor device 105 of FIG. 8 by second barrier layer 14 whose bang gap is larger than the band gap of first barrier layer 4. Note that second barrier layer 14 may be provided in any of semiconductor devices 101 to 104 without being limited to semiconductor device 105.

According to thus configured semiconductor device 106, it is possible to obtain, in addition to the same effects as those of semiconductor devices 101 to 105, an effect of reducing On-resistance of semiconductor device 106 and increasing maximum drain current since the concentration of 2DEG 7 which occurs directly beneath second barrier layer 14 increases.

### Variation 6

In the above described semiconductor devices 101 to 106, second barrier layer 6, 14 may contain n-type impurities for setting the band gap of second barrier layer 6, 14 to be larger than the band gap of channel layer 3. When an upper layer, middle layer, and lower layer are defined in this order from the side, where source electrode 9 and drain electrode 10 are formed, of second barrier layer 6, 14, n-type impurities may be added to any one of the upper layer, middle layer, and lower layer, or may be added to two or three layers. As one specific example, the concerned upper layer may be constituted of n-AlGaN/AlGaN, the middle layer of AlGaN/n-AlGaN/AlGaN, and the lower layer of AlGaN/n-AlGaN. Such a case will be described in Variation 6.

FIG. 10 is a cross-sectional view to show an example of the structure of a semiconductor device according to Variation 6. Semiconductor device 107 shown in FIG. 10 is configured by substituting second barrier layer 6 of semiconductor device 105 of FIG. 8 by second barrier layer 15 which is added with n-type impurities. Note that second barrier layer 15 may be provided in any of semiconductor devices 101 to 106 without being limited to semiconductor device 105.

According to thus configured semiconductor device 107, it is possible to obtain, in addition to the same effects as those of semiconductor devices 101 to 106, an effect of decreasing On-resistance and increasing maximum drain current of semiconductor device 107 since the concentration of 2DEG 7 which occurs directly beneath second barrier layer 15 increases.

### Variation 7

Although, in the above described semiconductor devices 101 to 107, second barrier layer 6, 14, 15 is in contact with channel layer 3, a spacer layer which is a nitride semiconductor having a band gap larger than that of second barrier layer 6, 14, 15 may be provided between second barrier layer 6, 14, 15 and channel layer 3. Such a case will be described in Variation 7.

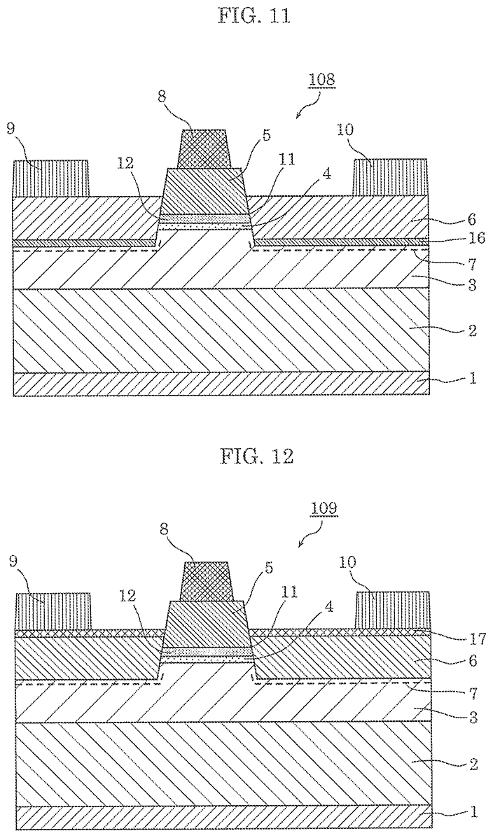

FIG. 11 is a cross-sectional view to show an example of the structure of a semiconductor device according to Variation 7. Semiconductor device 108 shown in FIG. 11 is configured by providing spacer layer 16 between second barrier layer 6 and channel layer 3 of semiconductor device 105 of FIG. 8.

Spacer layer 16 and second barrier layer 6 may be constituted of, for example, AlN and AlGaN, respectively, or may also be constituted of AlGaN having a larger compositional ratio of Al, and AlGaN having a smaller compositional ratio of Al, respectively. Note that spacer layer 16 may be provided in any of semiconductor devices 101 to 107 without being limited to semiconductor device 105.

According to thus configured semiconductor device 108, the same effects as those of semiconductor devices 101 to 107 can be obtained. Further, it becomes possible to increase the mobility of 2DEG 7 which occurs in channel layer 3 directly beneath spacer layer 16, thereby allowing high-speed operation. Moreover, it is possible to further increase carrier density, thereby decreasing On-resistance and increasing maximum drain current.

### Variation 8

Although, in the above described semiconductor devices 101 to 108, source electrode 9 and drain electrode 10 are provided on second barrier layer 6 without any explicit layer being interposed, a cap layer may be provided on second barrier layer 6, and source electrode 9 and drain electrode 10 are provided on the cap layer. Such a case will be described in Variation 8.

FIG. 12 is a cross-sectional view to show an example of the structure of a semiconductor device according to Variation 8. Semiconductor device 109 shown in FIG. 12 is configured by providing cap layer 17, which has a band gap smaller than that of second barrier layer 6, in contact with the upper surface of second barrier layer 6 of semiconductor device 105 of FIG. 8. Cap layer 17 may be constituted of, for example, i-GaN, n-GaN, i-InGaN, n-InGaN, and the like. Note that cap layer 17 may be provided in any of semiconductor devices 101 to 108 without being limited to semiconductor device 105.

According to thus configured semiconductor device 109, the same effects as those of semiconductor devices 101 to 108 can be obtained. Further, by physically separating the surface of the semiconductor layer (here, the surface of cap layer 17) from 2DEG 7 by an amount of the thickness of cap layer 17 without increasing concentration of 2DEG 7 which occurs directly beneath second barrier layer 6, it is possible to suppress the occurrence of current collapse.

### Variation 9

Although, in the above described semiconductor devices 101 to 109, channel layer 3 is configured in a single layer, the channel layer may be configured in a laminated body of multiple (for example, two) layers. Such a case will be described in Variation 9.

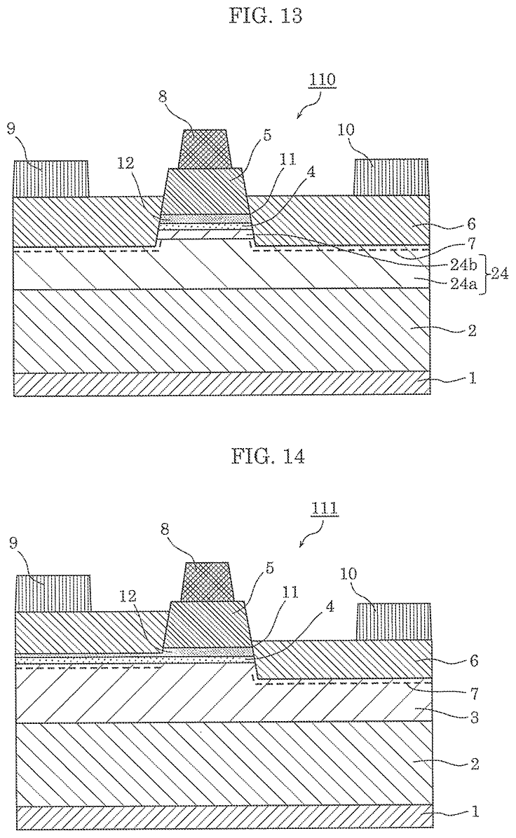

FIG. 13 is a cross-sectional view to show an example of the structure of a semiconductor device according to Variation 9. Semiconductor device 110 shown in FIG. 13 is configured by substituting channel layer 3 of semiconductor device 105 of FIG. 8 by channel layer 24. Channel layer 24 is made up of two layers of underlying first channel layer 24a and overlying second channel layer 24b. Where, the band gap of second channel layer 24b is different from the band gap of first channel layer 24a; and second channel layer 24b is formed only in an area where first channel layer 24a is formed in a plan view.

The band gap of first channel layer 24a may be larger than the band gap of second channel layer 24b. For example, first channel layer 24a may be constituted of AlGaN, InGaN, AlInGaN, or the like, and second channel layer 24b may be constituted of GaN.

Such a structure may be formed by, for example, performing over-etching when patterning of gate layer 5 is performed, to remove an unnecessary portion of gate layer 5 as well as entire second channel layer 24b underling directly beneath the unnecessary portion and a surface layer of first channel layer 24a.

Note that channel layer 24 may be provided in any of semiconductor devices 101 to 109 without being limited to semiconductor device 110.

According to thus configured semiconductor device 110, the same effects as those of semiconductor devices 101 to 109 can be obtained. Further, when second channel layer 24b is constituted of GaN, and first channel layer 24a is constituted of AlGaN, high-voltage resistant operation becomes possible. Further, when second channel layer 24b is constituted of GaN, and first channel layer 24a is constituted of InGaN, mobility and density of carrier increase, thus making it possible to decrease On-resistance and increase maximum drain current.

### Variation 10

Although, in the above described semiconductor devices 101 to 110, the lower surface of second barrier layer 6 is shown at the same height on the source side and the drain side, the height of the lower surface of the second barrier layer may not necessarily be the same on the source side and the drain side. Such a case will be described in Variation 10.

FIG. 14 is a cross-sectional view to show an example of the structure of a semiconductor device according to Variation 10. In semiconductor device 111 shown in FIG. 14, gate layer 5 is disposed on and in contact with a selected part of an upper surface of first barrier layer 4. Further, first barrier layer 4 is formed only in an area extending from below gate layer 5 to the side of source electrode 9 in a plan view, and second barrier layer 6 in that area is formed on first barrier layer 4. The lower surface of second barrier layer 6 is in contact with channel layer 3 on the side of drain electrode 10, and in contact with first barrier layer 4 (including diffusion layer 12 formed in first barrier layer 4) on the side of source electrode 9. That is, diffusion layer 12 may remain on the side of source electrode 9, but will be removed on the side of drain electrode 10.

Such a structure may be formed by, for example, performing over etching, which is deeper on the side of drain than on the side of source, when patterning of gate layer 5 is performed. Alternatively, over etching may not be performed on the side of source, and the lower surface of second barrier layer 6 is in contact with the upper surface of diffusion layer 12 (not shown). Note that the height of the lower surface of second barrier layer 6 may differ between the source side and the drain side not only in semiconductor device 111 but also in any of semiconductor devices 101 to 110.

Since, in a common FET (including HEMT), when a high voltage is applied, no high voltage will be applied between the gate and source, and diffusion layer 12 which remains on the side of the source is not likely to become a leakage path of gate current. For that reason, according to semiconductor device 111 configured as described above, the same effects as those of semiconductor devices 101 to 110 can be obtained. Moreover, resistance of 2DEG on the source side can form a 2DEG layer based on the sum of the first barrier layer and the second barrier layer, thus allowing to reduce On-resistance and to increase maximum drain current. At the same time, since diffusion layer 12, into which a p-type impurity has diffused, on the drain side is fully removed, it is possible to reduce gate leakage current at a high voltage, which flows in the p-type impurity diffusion layer.

### Manufacturing Method of Semiconductor Device

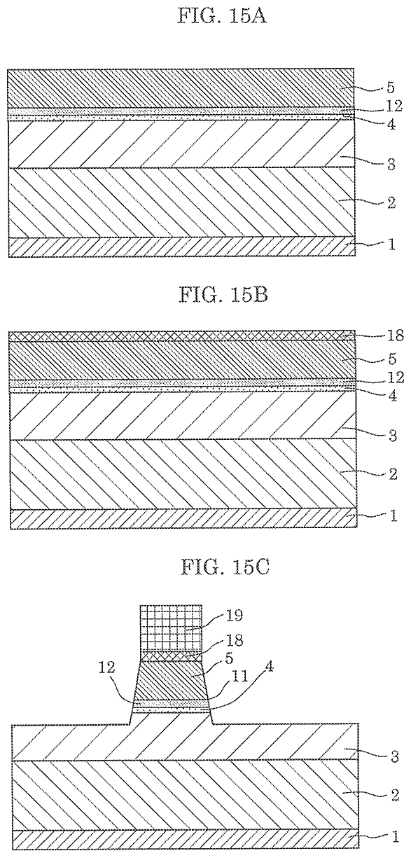

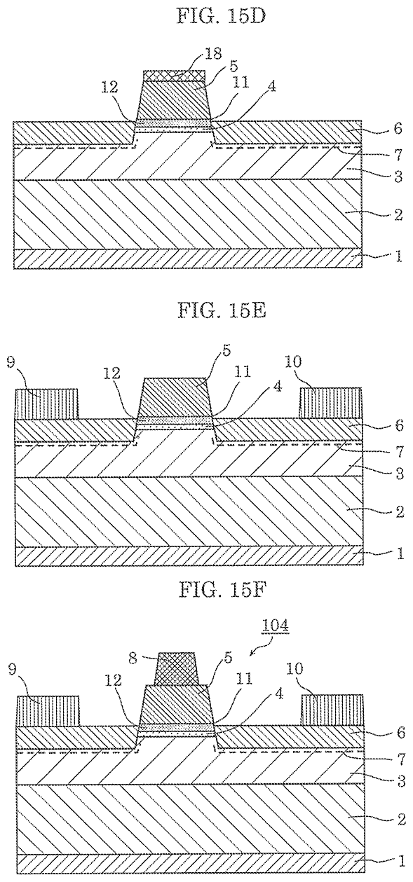

Next, a manufacturing method of a semiconductor device according to Embodiment 1 will be described with reference to FIGS. 15A to 15F. Note that the order of manufacturing process, process techniques to be utilized, and constituent materials will not be limited to the following examples. For example, hereinafter, for the sake of clarity, an example of manufacturing method of semiconductor device 104 will be described, but the same manufacturing method may be used to manufacture semiconductor devices 101 to 111.

First, as shown in FIG. 15A, buffer layer 2, channel layer 3, first barrier layer 4, and gate layer 5 are formed consecutively by epitaxy on substrate 1. For example, MOCVD is used as the epitaxy.

As described above, substrate 1 is for example an Si substrate of a (111) crystal plane, and besides substrates of sapphire, SiC, GaN, AlN, and the like can be used.

As buffer layer 2, for example, a single or plural layers of GaN, AlGaN, AlN, InGaN, or the like are formed. Although channel layer 3 is a single layer constituted of GaN in this embodiment, it may be a single layer constituted of InGaN, AlGaN, AlInGaN, or the like. Although first barrier layer 4 is constituted of AlGaN, it may be constituted of, for example, GaN, InGaN, AlInGaN, or the like depending on the material of channel layer 3. Although gate layer 5 is constituted of p-GaN which is a p-type group-III nitride semiconductor device, it may be a single layer of p-InGaN, p-AlGaN, p-AlInGaN, or the like.

When forming gate layer 5, a p-type impurity constituted of Mg (besides, may be C, Zn, or the like) is added at a concentration of 1E19 cm⁻³ to 1E20 cm⁻³. The concerned impurity may form diffusion layer 12 in first barrier layer 4 depending on the concentration of the concerned impurity and the process temperature for growing gate layer 5. The concerned diffusion layer may reach channel layer 3.

Next, as shown in FIG. 15B, mask layer 18 constituted of SiO₂ (besides, may be SiN, SiON, Al₂O₃, or the like) is formed on gate layer 5 by using PECVD (Plasma Enhanced CVD), LPCVD (Low Pressure CVD), thermal CVD, or the like.

Next, as shown in FIG. 15C, resist pattern 19 is formed on mask layer 18 by using photolithography, and mask layer 18, gate layer 5, and first barrier layer 4 (including diffusion layer 12) are selectively removed by using dry etching with resist pattern 19 being as a mask.

At this moment, it is possible to suppress leakage of gate current at high voltage operation by fully removing diffusion layer 12 in an area other than resist pattern 19, or by removing at least a portion of diffusion layer 12 where impurity concentration is more than or equal to 1E18 cm⁻³. On the other hand, when the diffusion layer remains without being fully removed, if an area in which impurity concentration is more than or equal to 1E18 cm⁻³ remains, leakage of gate current during high voltage operation occurs.

When diffusion layer 12 is formed only in first barrier layer 4, the depth of dry etching for removing diffusion layer 12 is enough if it is a depth which allows to fully remove first barrier layer 4. However, considering that there is variation in the depth of dry etching in a wafer plane, and that diffusion layer 12 may be formed reaching channel layer 3, channel layer 3 may be over etched to a depth of several nm to several tens of nm as shown in FIG. 15C.

Next, as shown in FIG. 15D, resist pattern 19 is removed by ashing or organic washing. Thereafter, AlGaN layer (besides, may be a layer of GaN, InGaN, AlInGaN, or the like) which becomes second barrier layer 6 is regrown in an area other than mask layer 18 by using MOCVD, etc.

Second barrier layer 6 may be regrown to a thickness of at least more than or equal to 20 nm, possibly more than or equal to 30 nm for suppressing current collapse. Second barrier layer 6 may be provided at a thickness not reaching the lower surface of gate layer 5 depending on the size and regrowth condition of mask layer 18. Further, second barrier layer 6 may be grown to a thickness to cover a part of the side surface of gate layer 5 as long as a part of gate layer 5 to which gate electrode 8 is to be connected later is exposed. Moreover, a cap layer may be formed on second barrier layer 6 (not shown).

Next, as shown in FIG. 15E, as source electrode 9 and drain electrode 10, electrodes constituted of a combination of one or more metals of Ti, Al, Mo, Hf, etc. are formed so as to be spaced apart from gate layer 5. Source electrode 9 and drain electrode 10 may be formed by photolithography, vapor deposition, sputtering, dry etching, or the like. Source electrode 9 and drain electrode 10 may be formed on second barrier layer 6, and may also be formed so as to be in contact with at least one of second barrier layer 6, 2DEG 7, and channel layer 3, by using a known ohmic recess structure.

Next, as shown in FIG. 15F, as gate electrode 8, electrodes constituted of a combination of one or more metals of Ti, Ni, Pd, Pt, Au, W, WSi, Ta, TiN, Al, Mo, Hf, Zr, etc. are formed on gate layer 5. Gate electrode 8 may be formed by photolithography, vapor deposition, sputtering, dry etching, or the like. Gate electrode 8 may be formed to be in contact with a part of gate layer 5, and gate electrode 8 and gate layer 5 may be in ohmic contact or Schottky contact with each other.

Semiconductor devices 101 to 111 are manufactured by using the manufacturing method described so far and manufacturing methods similar to those described above. Effects which can be obtained by semiconductor devices 101 to 111 are as described above, and description thereof will not be repeated here.

### Embodiment 2

### Structure of Semiconductor Device

Although, in semiconductor devices 101 to 111 shown in Embodiment 1, second barrier layer 6 covers a part of the side surface of gate layer 5, the second barrier layer may cover at least a part of the side surface of the gate layer and, for example, the second barrier layer may cover the entire side surface of the gate layer. Such a case will be described in Embodiment 2. Note that hereinafter, components equal to those of Embodiment 1 are denoted by the same symbols, and the above description are intended to apply to matters equivalent to those of Embodiment 1, and description thereof will be appropriately omitted.

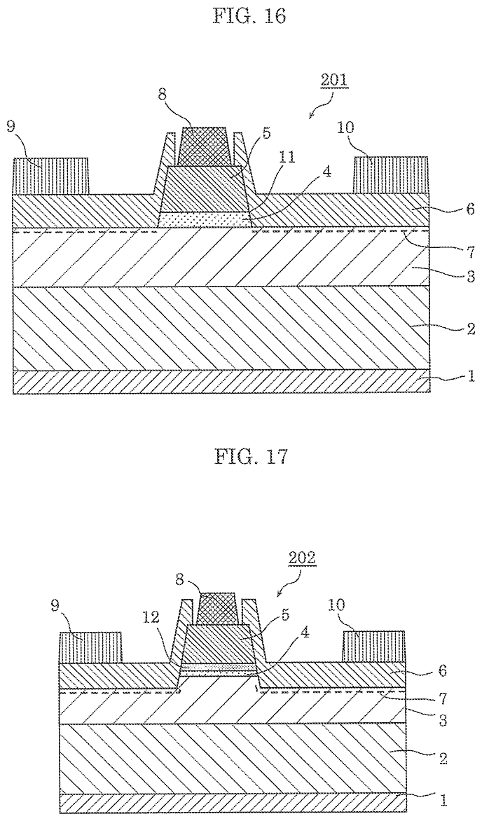

FIG. 16 is a cross-sectional view to show an example of a structure of a semiconductor device according to Embodiment 2. It will be specifically described with reference to FIG. 16. Semiconductor device 201 shown in FIG. 16 is, compared to semiconductor device 101 of FIG. 4, configured such that second barrier layer 6 is provided along the side surface of gate layer 5 and to a height exceeding the upper end of the side surface of gate layer 5, thus covering the entire side surface of gate layer 5. In this way, second barrier layer 6 may be regrown to a thickness to cover the entire side surface of gate layer 5 as long as a part of gate layer 5, to which gate electrode is to be connected later, is exposed. Note that second barrier layer 6 of such a shape may be provided in any of semiconductor devices 102 to 111, without being limited to semiconductor device 101.

According to semiconductor device 201 thus configured, the same effects as those of semiconductor devices 101 to 111 can be obtained. Further, by providing a thick second barrier layer 6 thereby physically keeping the surface of second barrier layer 6 and 2DEG 7 to be apart from each other in the vicinity of gate end 11 on the drain side where electric field is most concentrated, it is possible to reduce current collapse.

### Variation 11

Also, in the above described semiconductor device 201, as in semiconductor device 104 according to Variation 3, impurities which are contained in gate layer 5 when gate layer 5 is formed may diffuse into first barrier layer 4. Such a case will be described in Variation 11.

FIG. 17 is a cross-sectional view to show an example of the structure of a semiconductor device according to Variation 11. Semiconductor device 202 shown in FIG. 17 includes second barrier layer 6 similar to that of semiconductor device 201 of FIG. 16, diffusion layer 12 similar to that of semiconductor device 104 of FIG. 7 and over etched channel layer 3.

According to thus configured semiconductor device 202, both effects of semiconductor device 201 and semiconductor device 104 can be obtained.

### Manufacturing Method of Semiconductor Device

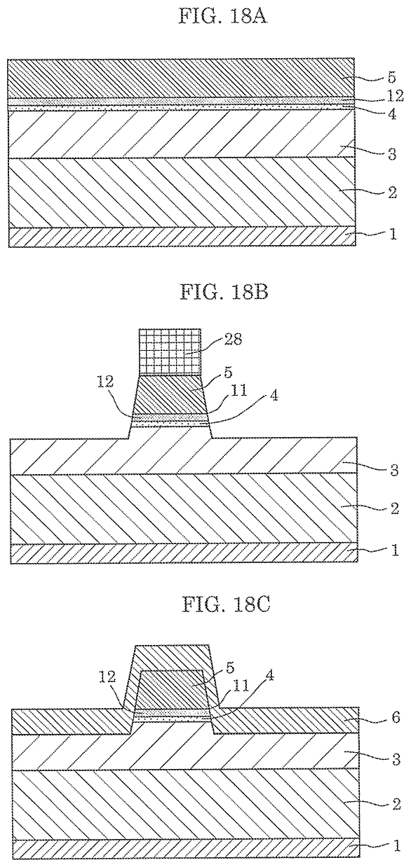

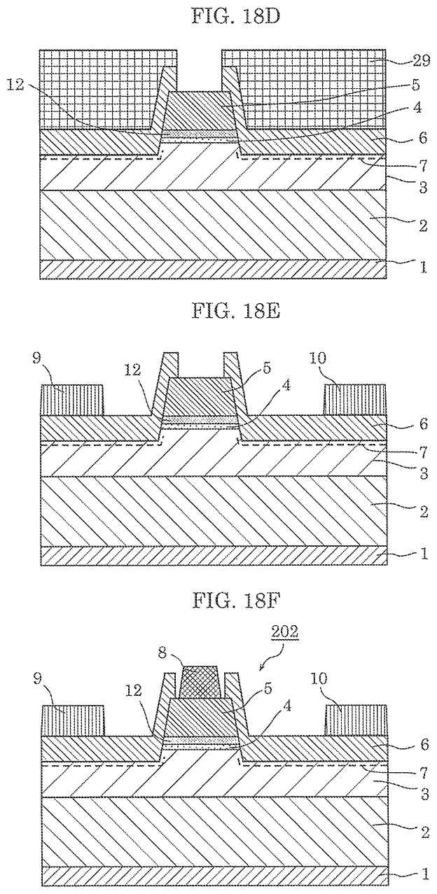

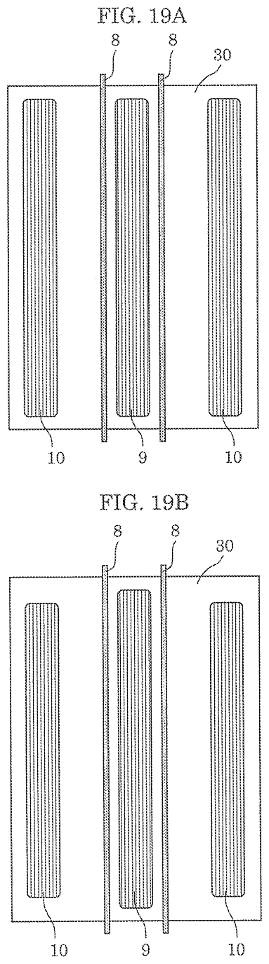

Next, a manufacturing method of a semiconductor device according to Embodiment 2 will be described with reference to FIGS. 18A to 18F. Note that the above description is intended to apply to matters equivalent to those of the manufacturing method of semiconductor device 101, and description thereof will be appropriately omitted. Moreover, the order of manufacturing process, process techniques to be utilized, and constituent materials will not be limited to the following examples. For example, hereinafter, for the sake of clarity, an example of manufacturing method of semiconductor device 201 will be described, but a similar manufacturing method may be used to manufacture semiconductor device 202.

First, as shown in FIG. 18A, buffer layer 2, channel layer 3, first barrier layer 4, and gate layer 5 are formed on substrate 1. At this moment, diffusion layer 12 is formed. Details of the material of each layer and the process are the same as those described in FIG. 15A.

Next, as shown in FIG. 18B, resist pattern 28 is formed by using photolithography, and gate layer 5 and first barrier layer 4 (including diffusion layer 12) are selectively removed by using dry etching. Details of removal of diffusion layer 12 and over etching of channel layer 3 are the same as those described in FIG. 15C.

Next, as shown in FIG. 18C, resist pattern 28 is removed by ashing and organic washing. Thereafter, an AlGaN layer (besides, may also be a layer of GaN, InGaN, AlInGaN, or the like) which becomes second barrier layer 6 is regrown over an area of the entire surface by using MOCVD, etc.

Second barrier layer 6 may be regrown to a thickness of at least more than or equal to 20 nm, possibly more than or equal to 30 nm to suppress current collapse. Second barrier layer 6 is also provided on gate layer 5, unlike in Embodiment 1.

Next, as shown in FIG. 18D, resist pattern 29 is formed by using photolithography, and second barrier layer 6 on gate layer 5 is selectively removed by using dry etching with resist pattern 29 being as a mask.

Next, as shown in FIG. 18E, resist pattern 29 is removed by using the material and process described with respect to FIG. 15E, and source electrode 9 and drain electrode 10 are formed to be spaced apart from gate layer 5.

Next, as shown in FIG. 18F, gate electrode 8 is formed so as to be in contact with a part of gate layer 5 by using the material and process described with respect to FIG. 15F.

Semiconductor devices 201 and 202 are manufactured by using the manufacturing method described above and a similar manufacturing method. The effects to be obtained by semiconductor devices 201 and 202 are as described above and description thereof will not be repeated here.

### Embodiment 3

In Embodiment 3, an example of the structure of an electrode of the semiconductor device described in Embodiments 1 and 2 will be described.

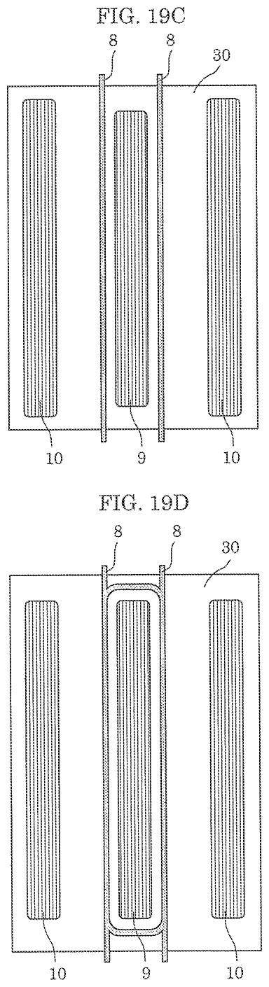

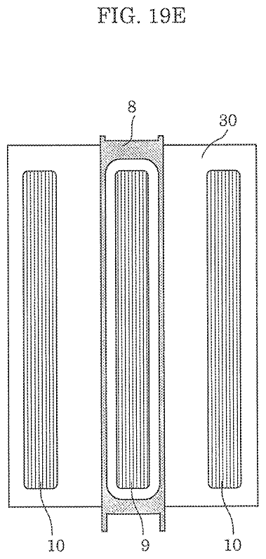

FIGS. 19A to 19E are each a plan view to show an example of the layout of a source electrode, a drain electrode, and a gate electrode to be provided in semiconductor devices 101 to 111, 201, and 202.

For example, as shown in FIG. 19A, source electrode 9 and drain electrode 10 may be in active area 30, and may have a width (vertical dimension in the figure) shorter than that of gate electrode 8. Moreover, source electrode 9 and drain electrode 10 may have the same width, and end parts of which may be aligned in a straight line in a plan view. As a result of this, electric field intensities at the end parts of source electrode 9 and drain electrode 10 can be made equal to each other. However, it is not necessary for source electrode 9 and drain electrode 10 to have the same width, and as shown in FIGS. 19B and 19C, the width of drain electrode 10 may be smaller or larger than that of source electrode 9.

Moreover, as shown in FIG. 19D, gate electrode 8 may fully surround source electrode 9 within active area 30. As a result of this, it is possible to reduce leakage current (source leakage current) between source and drain when the semiconductor device is in an Off-state. Further, since in an area surrounded by gate electrode 8 and a side of active area 30, electric charge may become floated thereby causing impairment of high speed operation, gate electrode 8 may be provided in a shape which will not result in such an area. Note that in FIGS. 19A to 19E, although a layout in which both source electrode 9 and drain electrode 10 are located entirely in active area 30 is illustrated, respective upper and lower ends of source electrode 9 and drain electrode 10 may be located outside active area 30. For example, only the upper ends of source electrode 9 and drain electrode 10 may be located outside active area 30, and only lower ends of source electrode 9 and drain electrode 10 may be located outside active area 30.

### Other Variations

So far, semiconductor devices according to plural aspects of the present disclosure have been described based on embodiments, however, the present disclosure will not be limited to those embodiments. Aspects in which various alterations conceived by the person skilled in the art are made to those embodiments, and aspects which are constructed by combining components in different embodiments can be included in the present disclosure as long as they do not depart from the spirit of the present disclosure.

For example, although, in the above description, semiconductor devices 102 to 111, and 202 have been described as respectively independent Variations 1 to 11, further different variations may be constituted by combining semiconductor devices 102 to 111, and 202.

### INDUSTRIAL APPLICABILITY

The semiconductor device of the present disclosure can be used for power devices as a HEMT which can realize a normally-off operation, and at the same time can significantly suppress gate leakage current and reduce current collapse.

What is claimed is:

1. A semiconductor device, comprising:
a substrate;
a channel layer which is constituted of a single layer of a nitride semiconductor disposed over the substrate and having a first band gap;
a first barrier layer which is a nitride semiconductor disposed on and in contact with a selected part of an upper surface of the channel layer and having a second band gap larger than the first band gap of the channel layer;
a gate layer which is a nitride semiconductor containing a p-type impurity, the gate layer being disposed on and in contact with the first barrier layer;
a second barrier layer which is a nitride semiconductor disposed in contact with both the channel layer and the first barrier layer, in an area where the gate layer is not disposed, the second barrier layer having a third band gap which is larger than the first band gap of the channel layer, and having a thickness and a band gap that are independently set with respect to the first barrier layer, the second barrier layer being a different layer distinguished from the first barrier layer;
a gate electrode which is disposed on the gate layer; and
a source electrode and a drain electrode which are spaced apart from the gate layer and disposed on the second barrier layer, wherein:
a cross sectional shape along a source-to-drain direction of the gate layer is a forward tapered shape having a top smaller than a bottom,
sidewalls of the first barrier layer and the gate layer are continuously connected,
a lower surface of the second barrier layer is located lower than a lower surface of the first barrier layer, and
the channel layer is continuous from a portion below the source electrode to a portion below the drain electrode.

2. The semiconductor device according to claim 1, wherein
a concentration of the p-type impurity contained in the first barrier layer is more than or equal to 1E18 cm−3, and
a concentration of the p-type impurity contained in the second barrier layer is less than 1E18 cm−3.

3. The semiconductor device according to claim 1, wherein
a thickness of the second barrier layer is larger than a thickness of the first barrier layer.

4. The semiconductor device according to claim 1, wherein
an upper surface of the second barrier layer is located higher than an upper surface of the first barrier layer.

5. The semiconductor device according to claim 1, wherein
a band gap of the second barrier layer is larger than a band gap of the first barrier layer.

6. The semiconductor device according to claim 1, wherein
the second barrier layer contains an n-type impurity.

7. The semiconductor device according to claim 1, wherein
the channel layer includes a lower layer of a first channel layer and an upper layer of a second channel layer,
a band gap of the second channel layer is different from a band gap of the first channel layer, and
the second channel layer is disposed only in an area where the first barrier layer is disposed in a plan view.

8. The semiconductor device according to claim 1, wherein
a concentration of the p-type impurity contained in the first barrier layer is more than or equal to 1E18 cm−3, and
a concentration of the p-type impurity contained in the channel layer directly beneath the second barrier layer is less than 1E18 cm−3.

9. The semiconductor device according to claim 1, further comprising
a spacer layer which is a nitride semiconductor having a band gap larger than the band gap of the second barrier layer, the spacer layer being disposed between the second barrier layer and the channel layer.

10. The semiconductor device according to claim 1, further comprising
a cap layer which is a nitride semiconductor disposed in contact with an upper surface of the second barrier layer, and having a band gap smaller than the band gap of the second barrier layer.

11. The semiconductor device according to claim 1, wherein
the gate layer is disposed on and in contact with a selected part of an upper surface of the first barrier layer,
the first barrier layer is disposed only in an area from below the gate layer to a side of the source electrode in a plan view, and
the second barrier layer in the area is disposed on the first barrier layer.

12. The semiconductor device according to claim 1, wherein
the second barrier layer covers at least a part of a side surface of the gate layer.

13. A semiconductor device, comprising:
a substrate;
a channel layer which is constituted of a single layer of a nitride semiconductor disposed over the substrate and having a first band gap;
a first barrier layer which is a nitride semiconductor disposed on and in contact with a selected part of an upper surface of the channel layer and having a second band gap larger than the first band gap of the channel layer;
a gate layer which is a nitride semiconductor containing a p-type impurity, the gate layer is disposed on and in contact with a selected part of an upper surface of the first barrier layer;
a second barrier layer which is a nitride semiconductor disposed in contact with both the channel layer and the first barrier layer, in an area where the gate layer is not disposed, the second barrier layer having a third band gap which is larger than the first band gap of the channel layer, and having a thickness and a band gap that are independently set with respect to the first barrier layer, the second barrier layer being a different layer distinguished from the first barrier layer;
a gate electrode which is disposed on the gate layer; and
a source electrode and a drain electrode which are spaced apart from the gate layer and disposed on the second barrier layer, wherein:
a cross sectional shape along a source-to-drain direction of the gate layer is a forward tapered shape having a top smaller than a bottom,
a lower surface of the second barrier layer is located lower than a lower surface of the first barrier layer, and
the channel layer is continuous from a portion below the source electrode to a portion below the drain electrode,
the first barrier layer is disposed only in an area from below the gate layer to a side of the source electrode in a plan view, and
the second barrier layer in the area is disposed on the first barrier layer.
